(19) United States
(12) Patent Application Publication
(10) Pub. No.: US 2003/0179598 A1
(43) Pub. Date: Sep. 25, 2003

(54) Device for selectively providing read-only data

(76) Inventor: Yu-Guang Chen, Taipei (TW)

Correspondence Address: RABIN & CHAMPAGNE, PC, 1101 14TH STREET, NW, SUITE 500, WASHINGTON, DC, 20005, US

(21) Appl. No.: 10/390,911

(22) Filed: Mar. 19, 2003

(30) Foreign Application Priority Data
Mar. 20, 2002 (TW) 091105309

(51) Int. Cl. G11C 5/06; G11C 8/00; G11C 5/00

(52) U.S. Cl. 365/63; 365/230.06; 365/189.08

(57) ABSTRACT

A device for selectively providing read-only data includes an inter-integrated circuit (I²C) controller, an AND-gate, a decoder, and m ROMs that each have different data that can be accessed by the I²C controller. M pads which connected to the AND-gate and the decoder are used as enable-signal input terminals. A specific pin in the chip is connected to one of the pads to receive the enable-signal and other pads for the enable-signal input terminals are connected during the packaging process so that they have constant voltage as the device is operating. When the status of the enable-signal changes, the decoder selects the ROM that corresponds to the specific pad and enables the I²C controller to access the data in the ROM.

This application claims the benefit of Taiwan application Serial No. 091105309, filed Mar. 20, 2002.

### BACKGROUND OF THE INVENTION

1. Field of the Invention

The invention relates in general to a data reading device, and more particularly to a read-only memory (ROM) data providing device.

2. Description of the Related Art

The electronics industry prospers due to development and innovative technology in fields such as semiconductors, and it is especially true for the field of personal computers (PCs). The speed of advancement for CPUs, peripherals, and storage mediums can only be described as amazing. Regarding storage mediums, memory modules have advanced to 168 pin dual in-line memory (DIMM) from the earlier 72 pin single in-line memory (SIMM); the 32 bit data transfer bandwidth has now been replaced by 64 bit bandwidth; and in today's computers 128M dynamic random access memory (DRAM), which has become the mainstream on the market, has greatly enhanced the efficiency of data transfer.

There are many DRAM chip manufacturers such as Winbond, Promos, and Powerchip Semiconductor Corp (PSC). There are no commonly agreed DRAM standards due to the different technical sources of the manufacturers, so their DRAMs have different parameters. Different DRAM chips require different configuration data (for different parameters) during the manufacturing process in order for them to work properly. For example, a DRAM chip manufactured by manufacturer A has parameter A while a DRAM chip manufactured by manufacturer B has parameter B. Data required in producing memory modules with DRAM chips of manufacturer A is different from data required in producing memory modules with DRAM chips of manufacturer B. Therefore, in practice, a serial presence detect (SPD) chip, which stores memory configuration data, is installed in the memory module to meet the different data configuration requirements.

The SPD chip indicates the parameters of the DRAM chips. When the memory module is mounted to the motherboard, the BIOS of the motherboard can set up the DRAM to work properly according to the configuration data stored in the SPD chip. Because the data stored in an SPD chip varies according to the type of the DRAM chips, the electronic erasable programmable read-only memory (EEPROM) is often employed to implement the SPD chip. Therefore, no matter which kind of DRAM chip is used in the memory module, the corresponding set of configuration data can be written into the SPD chip. When DRAM chips of manufacturer A are used to produce memory modules, parameter A can be written into the SPD chip. When DRAM chips of manufacturer B are used, parameter B can be written into the SPD chip. In this way, the same structure with a SPD chip can be employed in different memory modules although the corresponding memory configuration data are different.

Referring to FIG. 1, a conventional SPD chip is showed to be implemented by an inter-integrated circuit (I²C) controller 110 with an EEPROM 120. When an enable-signal D is fed into the I²C controller 110, the I²C controller 110 can produce control-signal CT and read data from the EEPROM 120. Please note that the I²C controller is a negative-edge-triggered device, which does not respond when the voltage of enable-signal D rises from low to high. When the enable signal voltage drops from high to low, the I²C controller is activated and reads data from the EEPROM. In this configuration, a logical 0 is indicated by a high level voltage and a logical 1 is indicated by a low level voltage for the I²C controller.

Nowadays, the cost of EEPROMs is high because of the complex manufacturing process and a high defect rate. High EEPROM costs indirectly increase the production cost of DRAMs that use EEPROMs as the SPD. Manufacturers of SPD chips also have to write different sets of data into the EEPROMs according to the type of DRAM chips. Writing data into the EEPROM is a time consuming process, increasing production costs and decreasing price competitiveness.

In summary, there are at least two drawbacks to using EEPROMs as SPD chips:

1. EEPROMs have a higher cost, which increases DRAM production costs.

2. The time required to write data into EEPROMs is longer, so speed and efficiency are reduced and price competitiveness is lost.

### SUMMARY OF THE INVENTION

It is therefore an objective of the invention to provide a device for selectively providing read-only data, with read-only memory (ROM) instead of EEPROM in order to reduce production costs.

It is another objective of the invention to provide a device for selectively providing read-only data, with ROM instead of EEPROM in order to reduce the manufacturing time required and therefore to enhance the competitive advantages of the products.

The invention achieves the above-identified objectives by providing a device for selectively providing read-only data, as briefly described below:

The device for selectively providing read-only data includes an I²C controller, an AND-gate, a decoder, and m ROMs each of which has different data that can be read by the I²C controller. In this design, m pads are connected to both the AND-gate and the decoder to be used as enable-signal input terminals. During the packaging process of a chip according to the invention, a designated pin of the chip is connected to one pad specified to receive an enable-signal and the other pads are connected to a fixed voltage, e.g. a high level voltage. Thus, when the enable-signal changes, e.g. from the high level voltage to a low level voltage, the decoder can select the ROM that corresponds to the specified pad and the AND-gate also outputs an output signal according to the enable-signal, thereby enabling the I²C controller to read data in that ROM.

Other objectives, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) shows a conventional SPD chip.

FIG. 2 shows a device for selectively providing read-only data according to a preferred embodiment of invention in block diagram form.

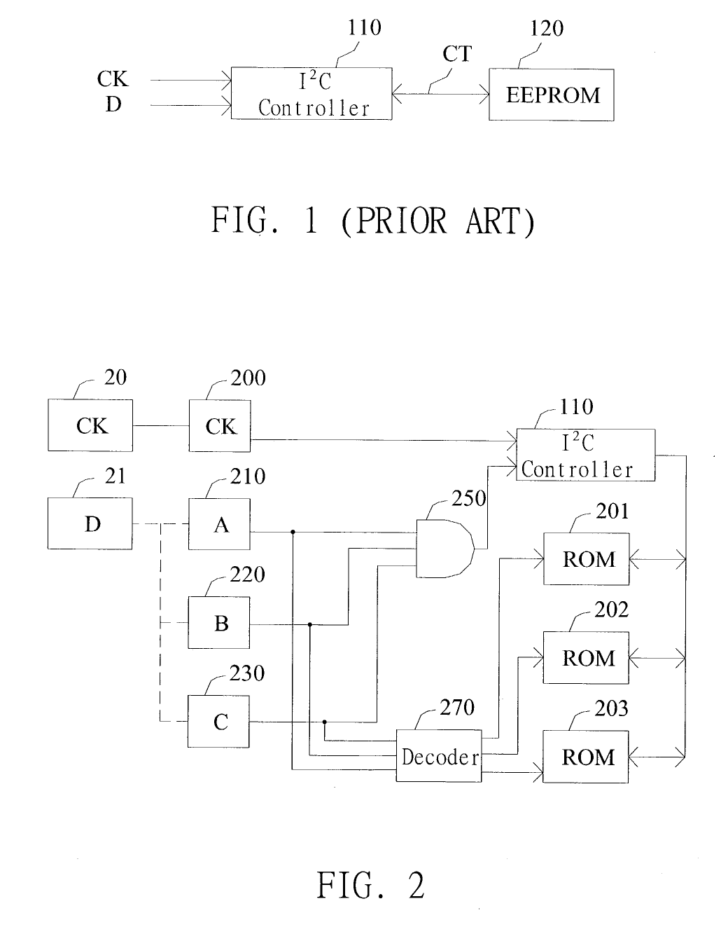

### DETAILED DESCRIPTION OF THE INVENTION

EEPROMs have been traditionally used as SPD chips and the DRAM configuration data is written into them permanently. After the memory module has been produced, the configuration data is only read from the SPD chip and no data will be written into the SPD chip. According to the invention, ROMs are used to replace the EEPROM in order to reduce production costs. For example, when the manufacturer employs three different types of DRAM chips to produce respective memory modules where SPD chips based-on ROMs are used, three sets of configuration data associated with the three types of DRAM chips are required. Each SPD chip internally can include three ROMs that store the three sets of configuration data in order to fulfil the requirements of the three different types of DRAM chips. Subsequently, three different types of SPD chips can be created to provide the configuration data individually corresponding to the three types of DRAM chips just by making corresponding modifications in the packaging process.

For example, if the DRAM chips that have parameter A are used to produce memory modules, data A in the SPD chip is required for configuration, and therefore only the ROM that contains data A needs to be read for the DRAM module to work properly. Similarly, if the DRAM chips that have parameter B are used to create memory modules, data B in the SPD chip is required for configuration, and therefore only the ROM that contains data B needs to be read for the DRAM module to work properly. If the DRAM chips that have parameter C are used to produce memory modules, data C in the SPD chip is required for configuration, and therefore only the ROM that contains data C needs to be read for the DRAM module to work properly. In real applications, when manufacturing an SPD chip that corresponds to DRAM chip A, only the pad associated with the ROM containing data A needs to be made a pad-to-pin connection in order to read its data while the other two pads associated with the ROMs are not read and are connected in such a way that they have a fixed voltage as the memory module is operating. In this way, the SPD chip corresponding to DRAM chip A is achieved after the packaging. Similarly, during the manufacturing of the SPD chip corresponding to DRAM chip B, only the pad associated with the ROM containing data B needs to be made a pad-to-pin connection; and during the manufacturing of the SPD chip corresponding to DRAM chip C, only the pad associated with the ROM containing data C is required to be made a pad-to-pin connection. Other explanations of the circuit structure related to the SPD chips will be given below.

FIG. 2 shows a device for selectively providing read-only data according to a preferred embodiment of the invention in block diagram form. An SPD chip can be created according to the device shown in FIG. 2. As shown in FIG. 2, the SPD chip includes an I²C controller 110, an AND gate 250, decoder 270, and several ROMs, such as ROMs 201, 202, and 203. Specifically, ROM 201 can store data A corresponding to DRAM chip A; ROM 202 can store data B corresponding to DRAM chip B; and ROM 203 can store data C corresponding to DRAM chip C. The internal circuit of the chip uses a number of pads which are connected to corresponding pins as its input and output terminals. In this way, the chip further includes a number of input terminals, such as pads 200, 210, 220, and 230. Pad 200, which is connected to pin 20 of the chip, is used as the clock-signal input terminal of the I²C controller 110 for receiving the clock signal CK and feeding it into the I²C controller 110. Pad 210, 220, and 230, which can be connected to pin 21 of the chip, are used as enable-signal input terminals that receive the enable-signal D and feed it into the I²C controller 110.

It is noted that if pad 210 has been connected to pin 21 in packaging of the chip, pads 220 and 230 must be fixed at a constant voltage in order for data A in the ROM 201 to be read when the enable-signal D is fed into pad 210 from pin 21. In other words, this device for selectively providing read-only data can be used as the SPD chip for DRAM chip A. Similarly, in order to create an SPD chip for DRAM chip B, pad 220 is connected to pin 21, and pads 210 and 230 can be connected in a way so that pads 210 and 230 are fixed at a constant voltage during operation. Further, in order to create an SPD chip for DRAM chip C, pad 230 can be connected to pin 21, and pads 210 and 220 can be connected in a way so that the two pads are fixed at a constant voltage. ROMs 201, 202, and 203 can be regarded as being associated with pads 210, 220, 230 respectively with respect to pad-to-pin connection in packaging. The operations of these circuits are explained below.

In practice, the clock-signal CK can be fed into the I²C controller 110 via pin 20 connected to pad 220. The AND-gate 250 is connected to the three enable-signal input terminals, i.e. pads 210, 220, and 230, in order to receive the enable-signal. If pad 210 is connected to pin 21 during the packaging process in order to receive the enable-signal and pads 220 and 230 are fixed at high voltage, the I²C controller 110 does not respond when the enable-signal is high, which causes the output of the AND-gate 250 to be high; when the enable-signal drops from high to low, the output of the AND-gate 250 also becomes low, and the I²C controller 110 responds because it is a negative-triggered device. In other words, the signal at the output of the AND-gate 250 is equivalent to the enable-signal D, and the I²C controller 110 can determine when to access data according to the status of the output of the AND-gate 250. Since pad 210 is connected to pin 21 and the I²C controller 110 is connected to pads 210, 220, and 230, the decoder 270 is employed to enable the I²C controller 110 to read the data in ROM 201 only. As shown in FIG. 2, the enable-signal input terminals, i.e. pads 210, 220, and 230, are also the input terminals of the decoder 270. Because pads 220 and 230 are fixed at a high voltage, when the enable-signal D drops from high voltage to low voltage, the voltage at pad 210 drops from high voltage to low voltage as well. The decoder 270 can be accordingly designed to decode the voltage level change at pad 210 so as to enable ROM 201 and disable ROMs 202 and 203. Therefore, when the voltage of the enable-signal D drops from high to low, the I²C controller 110 accesses only data A in ROM 201 (because ROM 202 and 203 are both disabled), and the device for selectively providing read-only data can be used as the SPD chip for DRAM chip A.

In this way, the device for selectively providing read-only data can also be used as the SPD chip for DRAM chip B. During the packaging process, pad 220 is connected to pin 21 as a terminal to receive enable-signal D and pads 210 and 230 are connected so that they can be at a high voltage when the SPD chip is operating. During the SPD is operating, when enable-signal D changes from high to low, the decoder 270 can decode this change so as to enable ROM 202 and the AND-gate 250 outputs a signal equivalent to enable-signal D to the I²C controller to enable it to access data B in ROM 202. The device for selectively providing read-only data now serves as an SPD chip for DRAM chip B. Similarly, the device for selectively providing read-only data can be modified during its packaging process to produce an SPD chip for DRAM chip C by connecting pad 230 to pin 21 as a terminal to receive enable-signal D, and connecting pads 210 and 220 so that they are fixed at a high voltage as the SPD chip operating.

As described above, an SPD chip, which is for providing specific data, can be produced by modifying a few steps in packaging a device for selectively providing read-only data. Three different data, for example, can be pre-written into three different ROMs of the device, and a specific ROM that the I²C controller of the device accesses can be determined by making pad-to-pin connection accordingly during the packaging process. In this way, it no longer needs to consume time on writing data into EEPROMs in manufacturing. Further, four or more ROMs can also be included in the circuit for storing more sets of data. The device for selectively providing read-only data can be packaged accordingly so as to produce four or more different types of SPD chip. This greatly enhances the flexibility of the chip's industrial applications. The chip circuit is often small, but the pad occupies a large area; therefore, the size of the chip will not be affected by the number of ROMs. The production process of the chip becomes more efficient and the utilization percentage of the chip increases as the number of ROMs increases. Furthermore, if the data in the ROM needs to be modified, only the connections of the metal layer need to be changed during the semiconductor production process. It is relatively easy and the flexibility of the chip creates extra value.

It is noted that the device of selectively providing read-only data of the invention can be applied to other control devices and systems, such as a control chip for display monitors, although the SPD chip for use in DRAM modules is illustrated according to the invention in the above embodiment.

The preferred embodiment of the invention as described above has at least the following advantages:

1. The EEPROM is replaced by ROM, and therefore the production cost is reduced.

2. The EEPROM is replaced by ROM, and no time is required to write data into the EEPROM, thereby increasing the product's competitive advantages.

3. Only the connections in the metal layer need to be changed when the data needs to be modified, making it easier and faster.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A device for selectively providing read-only data, comprising:
m read-only memories (ROMs), each of which stores data, where m is an integer greater than one;
m enable-signal input terminals for receiving an enable-signal, wherein the enable-signal is received by an nth enable-signal input terminal of the m enable-signal input terminals and n is an integer not greater than m;
an AND-gate, coupled to the m enable-signal input terminals, for outputting an output signal that is equivalent to the enable-signal;
a decoder, coupled to the m enable-signal input terminals and the m ROMs, for selecting the ROM that corresponds to the nth enable-signal input terminal from the m ROMs; and
an inter-integrated circuit (I²C) bus controller, coupled to the AND-gate and the m ROMs, for reading data from the ROM that is selected by the decoder according to the output signal of the AND-gate.

2. The device according to claim 1, which is used as an SPD chip.

3. The device according to claim 2, wherein the SPD chip is embedded in a dynamic random access memory (DRAM) module.

4. The device according to claim 1, which is used as a control chip of a display device.

5. The device according to claim 1, wherein the m enable-signal input terminals are pads.
